(19) United States
(12) Patent Application Publication
(10) Pub. No.: US 2006/0234512 A1
(43) Pub. Date: Oct. 19, 2006

(54) Plasma processing apparatus and plasma processing method

(75) Inventors: Mitsuhiro Yuasa, Tokyo (JP); Koji Homma, Tokyo (JP)

Correspondence Address: CROWELL & MORING LLP;INTELLECTUAL PROPERTY GROUP, P.O. BOX 14300, WASHINGTON, DC, 20044-4300, US

(73) Assignee: TOKYO ELECTRON LIMITED, Tokyo (JP)

(21) Appl. No.: 11/453,887

(22) Filed: Jun. 16, 2006

Related U.S. Application Data
(62) Division of application No. 10/385,659, filed on Mar. 12, 2003.

(30) Foreign Application Priority Data
Mar. 14, 2002 (JP) 2002-070845

(51) Int. Cl. H01L 21/302

(52) U.S. Cl. 438/710

(57) ABSTRACT

A plasma processing apparatus and method preferably used when processing a wafer by means of plasma etching, able to prevent contamination of a wafer or a chamber. The plasma processing apparatus converts a process gas into plasma, sprays the process gas from a spray nozzle 24a to a wafer 2 installed on an XYZ table 28, and processes the wafer 2. As the process gas, use is made of a mixture of SF₆ (sulfur hexafluoride) gas, Ar (Argon) gas, and O₂ (oxygen) gas, and the volume ratio of the O₂ (oxygen) gas to the SF₆ gas is in a range from 11% to 25%.

### CROSS REFERENCE TO RELATED APPLICATIONS

This application is a divisional application of U.S. patent application Ser. No. 10/385,659, filed on Mar. 12, 2003, which claims priority under 35 U.S.C. § 119 to Japan Patent Application No. 2002-070845, filed Mar. 14, 2002, the entire disclosures of which are herein expressly incorporated by reference.

### BACKGROUND OF THE INVENTION

1. Field of the Invention

The present invention relates to an apparatus and method used in plasma processing, particularly, to an apparatus and a method preferably used when processing a wafer by means of plasma etching.

2. Description of the Related Art

In a semiconductor device manufacturing process, the dry etching technique is widely used for processing a wafer. For example, dry etching is performed by using a plasma processing apparatus, and the plasma processing apparatus is configured to generate plasma using microwaves to excite ions and radicals and to etch a wafer by them.

Recently, a method has been utilized to perform plasma etching in local areas by spraying process gas plasma from a nozzle onto a wafer. This method is used when performing dicing for cutting a wafer into individual semiconductor devices.

In a plasma processing method of the related art (plasma etching method), SF₆ (sulfur hexafluoride) gas and Ar (Argon) gas are used as the process gas.

In the above plasma processing method of the related art, it is the SF₆ and the Ar gas only that are used as the process gas.

However, when a mixture consisting of SF₆ gas and Ar gas only is used as the process gas, there arises a problem that the SF₆ molecules in SF₆ gas disintegrate, and sulfur (S) is generated and adheres to a wafer and the wall of a chamber. If sulfur adheres to a wafer and the wall of a chamber, the adhered regions become white and impure.

Further, when sulfur is deposited onto a wafer, it functions as a resist and prevents the excited ions and radicals from acting on the wafer surface, leading to degradation of the etching rate. In addition, regarding cleaning sulfur adhering to the chamber wall, because such kind of cleaning has to be done at short intervals, it turns out to be quite troublesome.

Furthermore, in a dicing process, in order that the semiconductor devices are not scattered after a wafer is cut into individual chips, dicing is performed while keeping the wafer attached to a tape using an adhesive agent. As shown above, in the course of etching, excited ions and radicals exist inside a chamber, so, there arises a problem that carbon contained in the adhesive agent reacts with the excited ions and radicals, especially with fluoride (F), and CFx is generated and adheres to the wafer and chamber wall in a way similar to sulfur as mentioned above.

### SUMMARY OF THE INVENTION

Accordingly, it is a general object of the present invention to solve the above problems of the related art.

A more specific object of the present invention is to provide an apparatus and a method able to prevent contamination of a wafer or a chamber in plasma processing.

To attain the above object, according to a first aspect of the present invention, there is provided a plasma processing apparatus for converting a process gas into plasma, spraying said process gas from a spray nozzle to a substrate installed on a stand, and processing a surface of said substrate, wherein a mixture of SF₆ (sulfur hexafluoride) gas, Ar (Argon) gas, and O₂ (oxygen) gas is used as said process gas, and the volume ratio of the O₂ (oxygen) gas to the SF₆ gas is in a range from 11% to 25%.

To attain the above object, according to a second aspect of the present invention, there is provided a method of dividing a wafer into a plurality of individual semiconductor devices comprising the steps of forming grooves cut into a front surface of said wafer, said grooves demarcating circuits of said semiconductor devices formed on said front surfaces of said wafer, polishing a back surface of said wafer while the front surface of said wafer is fixed to a support member, and plasma etching the back surface of said wafer by a process gas and thereby dividing said wafer into the semiconductor devices, said process gas including a mixture of SF₆ (sulfur hexafluoride) gas, Ar (Argon) gas, and O₂ (oxygen) gas, wherein the volume ratio of the O₂ gas to the SF₆ gas is in a range from 11% to 25%.

To attain the above object, according to a third aspect of the present invention, there is provided a method of dividing a wafer into a plurality of individual semiconductor devices comprising the steps of forming masks on the front surface of said wafer for masking each said semiconductor device formed on the front surface of the wafer, plasma etching the front surface of said wafer between the masks to a predetermined depth using a process gas including a mixture of SF₆ (sulfur hexafluoride) gas, Ar (Argon) gas, and O₂ (oxygen) gas, wherein the volume ratio of the O₂ gas to the SF₆ gas is in a range from 11% to 25%, polishing a back surface of said wafer while the front surface of said wafer is fixed to a support member, and etching the back surface of said wafer and thereby dividing said wafer into the semiconductor devices.

According to the above inventions, because an appropriate amount of oxygen (the volume ratio of O₂ to the SF₆ gas is in a range from 11% to 25%) is supplied, even the SF₆ gas disintegrates and sulfur is generated, or even if C is generated from the adhesive agent, they are combined with oxygen (O₂) and turn into gas. Due to this, contamination attachment to the wafer or the chamber does not happen. So the etching rate of the wafer can be maintained, at the same time cleaning of the chamber can be easily performed.

Other objects, advantages and novel features of the present invention will become apparent from the following detailed description of the invention when considered in conjunction with the accompanying drawings.

### BRIEF DESCRIPTION OF THE DRAWING FIGURES

FIG. 1 is a view of a configuration of a plasma processing apparatus utilizing a plasma processing method according to an embodiment of the present invention;

FIG. 2 is a view of a manufacturing process for showing a plasma processing method according to an embodiment of the present invention;

FIG. 3 is a view showing a rate of occurrence of a defective wafer when the volume ratio of the O₂ gas to the SF₆ gas is changed; and

FIG. 4 is a view showing a variation of an etching rate when the volume ratio of the O₂ gas to the SF₆ gas is changed.

### DETAILED DESCRIPTION OF THE DRAWINGS

Below, preferred embodiments of the present invention will be explained with reference to the accompanying drawings.

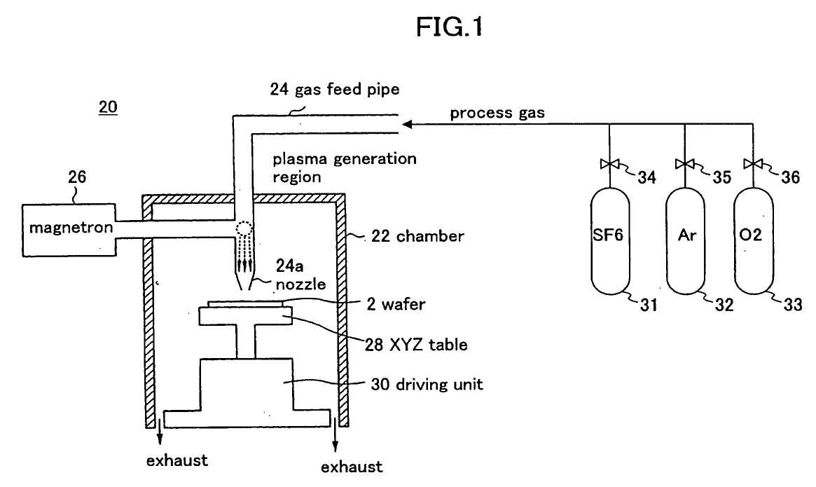

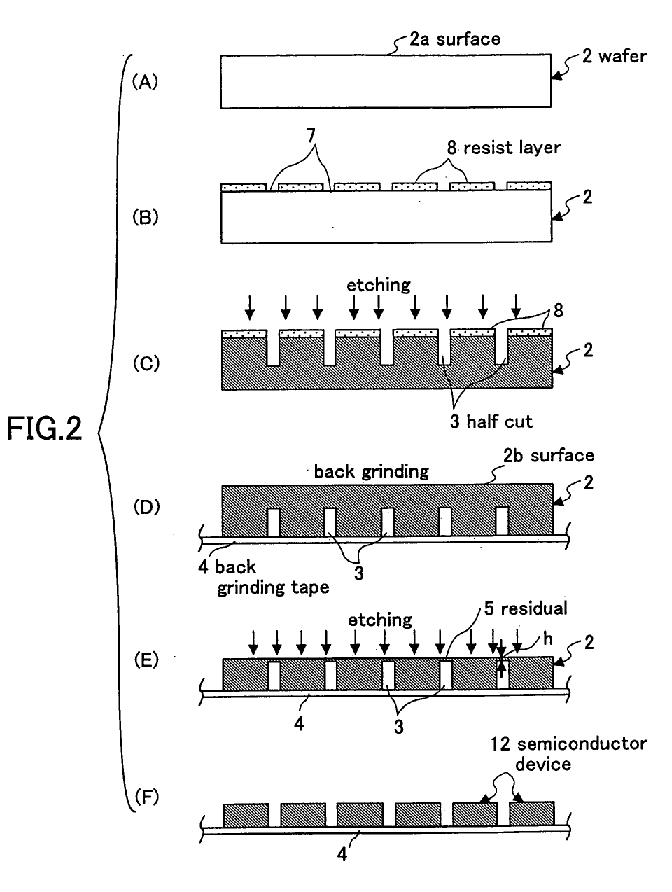

FIG. 1 and FIG. 2 are views for explaining a plasma processing apparatus and a plasma processing method according to an embodiment of the present invention. FIG. 1 shows a configuration of a plasma processing apparatus 20, and FIG. 2 is a view showing a dicing process performed by using the plasma processing apparatus 20.

First, the configuration of the plasma processing apparatus 20 will be explained with reference to FIG. 1. The plasma processing apparatus 20 shown in FIG. 1 generally includes a chamber 22, a process gas feed pipe 24, a magnetron (gas conversion unit) 26, an XYZ table (supporting unit) 28, a driving unit 30, and gas cylinders 31 through 33.

The chamber 22 is connected to a vacuum pump or other exhausting means so that a desired low pressure environment can be formed within the chamber 22. The XYZ table 28 serving as a loading platform is installed in the chamber 22, and a wafer 2, the object to be processed, is placed on the XYZ table 28. Driven by the driving unit 30, the XYZ table 28 is able to move in X, Y, Z directions.

The nozzle (spraying unit) 24a extending from the gas feed pipe 24 is mounted above the XYZ table 28, and the process gases from gas cylinders 31 through 33 are supplied to the nozzle 24a.

The magnetron 26 is connected above the nozzle 24a, and the high frequency electromagnetic wave from the magnetron 26 is applied to the process gas coming from the gas feed pipe 24, thereby plasma is generated. The plasma from the nozzle 24a irradiates a local area of the wafer 2, and wafer 2 is partially etched due to action of the plasma.

The site irradiated by the plasma can be changed by driving the XYZ table 28 in the X, Y directions (the horizontal plane) using the driving unit 30 to move the wafer 2 relative to the nozzle 24a. Further, the distance between the nozzle 24a and the wafer 2 can also be adjusted by moving the XYZ table 28 in the Z direction (the vertical direction).

The process gas feed pipe 24 is connected to the gas cylinders 31 through 33. In detail, the process gas feed pipe 24 is connected to the SF₆ gas cylinder 31 filled with SF₆ gas, the Ar gas cylinder 32 filled with Ar gas, and O₂ gas cylinder 33 filled with O₂ gas.

Furthermore, between the process gas feed pipe 24 and the gas cylinders 31 through 33, controlling valves 34 through 36 are respectively attached to gas cylinders 31 through 33, and by controlling the opening level of controlling valves 34 through 36, it is possible to change the constituent volume ratio of the process gas (containing SF₆ gas, Ar gas, and O₂ gas) supplied to chamber 22.

Next, referring to FIG. 2, an example will be presented of an embodiment of a plasma processing method using the plasma processing apparatus 20. In this embodiment, explanation will be made by taking as an example the dicing processing for wafer 2 in the plasma processing apparatus 20.

FIG. 2A shows the wafer 2 before the dicing processing. At this step, a number of semiconductor devices are formed on wafer 2, and circuits constituting these semiconductor devices are formed on the surface 2a of wafer 2.

First, resist layers 8 are formed on wafer 2. FIG. 2B shows the wafer 2 formed with the resist layers 8. The resist layers 8 serve as masks in the course of etching as shown later, so they are formed so that each has a size able to at least cover the area of the circuits of a semiconductor device.

The resist layers 8 are not formed at positions 7 on wafer 2 where the wafer 2 will be cut to separate the semiconductor devices (hereinafter, these separation positions will be referred to as dicing lines). That is, dicing lines 7 are uncovered on the surface of wafer 2.

After the resist layers are formed, as shown in FIG. 2C, partial plasma etching is performed (etching step) for wafer 2 by using the plasma processing apparatus 20. In detail, SF₆ gas, Ar gas, and O₂ gas, whose flow rates are controlled by the respective controlling valves 34 through 36 shown in FIG. 1, are supplied to the chamber 22 from the process gas feed pipe 24. The mixed gas is converted into plasma by the magnetron 26 and is sprayed onto the wafer 2 from the nozzle 24a. In this embodiment, the volume ratio of O₂ gas to SF₆ gas is set in a range from 11% to 25% in this step. This setting of the volume ratio can be easily attained by adjusting the controlling valves 34 through 36.

In plasma etching, the surface formed by etching is substantially parallel with the direction of plasma, that is, the surface formed by etching is substantially perpendicular to the front surface (or the rear surface) of the wafer 2, and thus division of wafer 2 can be performed at a high processing precision.

In plasma etching, there are block plasma etching in which wafer 2 as a whole is irradiated and etched by plasma at the same time, and partial plasma etching in which the density of plasma is enhanced locally for irradiation.

Since the whole surface of wafer 2 is etched at the same time, block plasma etching is effective for shortening the time (etching time) needed for separating the semiconductor devices 12. However, in the block plasma etching, when portions of different thicknesses exist in wafer 2, if processing is controlled so as to etch thicker portions completely, thinner portions will be over-etched. To the contrary, if the etching process stops when thinner portions are etched completely, thicker portions might not be etched sufficiently, leaving remnants.

In contrast, with partial plasma etching, it is easy to control etching depth, for example, it is possible to carry out etching appropriately for either thicker portions or thinner portions, and wafer 2 can be etched under the best condition.

In the etching step shown in FIG. 2C, dicing lines 7 of wafer 2 are etched. That is, by moving the XYZ table 28 with the driving unit 30, plasma from nozzle 24a is locally irradiated to wafer 2 along dicing lines 7. During this processing, as mentioned above, since resist layers 8 are formed on wafer 2 other than dicing lines 7, those regions of wafer 2 formed with the semiconductor devices 12 are not etched, thus damage to circuits of the semiconductor devices 12 can be prevented.

Note that the semiconductor device separation apparatus 20 related to the present embodiment is configured so that the wafer 2 is movable relative to the nozzle 24a, but the present invention is not limited to this. That is, nozzle 24a can also be set movable relative to wafer 2, or both of them can be movable.

In the etching processing by semiconductor device separation apparatus 20, if wafer 2 is a 200 mm wafer, and its thickness is 750μm the etching depth from the surface 2a is set to 20μm to 150μm. That is, in the present embodiment, wafer 2 is not cut completely, but grooves are formed in the middle of wafer 2 (hereinafter, these grooves are referred to as half cuts 3). Width of the half cuts 3 is 10 μm to 20 μm.

After the etching step for forming the above half cuts 3 is finished, resist ashing is carried out to remove the resist layers 8 and to clean wafer 2. Then, wafer 2 is reversed upside down, and attached to a back grind tape 4. For example, wafer 2 is attached to the tape 4 by an adhesive agent (not shown). After being attached to the back grind tape 4, the surface 2a of wafer 2 (the surface formed with circuits) attached to the tape 4 is now the lower surface in FIG. 2D. The rear surface 2b of wafer 2 is now the upper surface in FIG. 2D and is exposed.

After wafer 2 is attached to the back grind tape 4 as shown above, wafer 2 is installed in a back grind apparatus, and as shown in FIG. 2D, mechanical polishing is performed on the rear surface 2b of wafer 2 (polishing step). As shown above, wafer 2 has a thickness of 750 μm, so, in the present state, thicknesses of the semiconductor devices formed from wafer 2 are still too thick.

By polishing the rear surface 2b of wafer 2 (the surface opposite to that formed with circuits), wafer 2 becomes thin, thus semiconductor devices 12 are thinned. Such kind of polishing is called back grind.

In the above polishing step of the present embodiment, wafer 2 is polished so as to reduce thickness by 600 μm to 730 μm. But since the rear surface 2b of wafer 2 is polished mechanically in the present embodiment, the rear surface 2b of wafer 2 can be reduced to a preset thickness in a shorter time than if etching were used. In the polishing step, as shown in FIG. 2E, polishing is continued until the thickness of wafer 2 becomes a preset value (for example, 20 μm to 150 μm).

In the polishing step, wafer 2 is not polished down to the thickness of the semiconductor devices 12, but just down to a preset value, leading to a large remaining thickness of wafer 2. Due to this, the half cuts 3 do not communicate with the rear surface 2b, and the semiconductor devices 12 remain connected with each other by the residual portions 5. Thicknesses of residuals 5 are set to 10 μm to 50 μm.

After the polishing step is finished, a separation step is performed to etch the semiconductor devices 12 to a preset thickness. By this step, the residuals 5 are removed, and as shown in FIG. 2F, wafer 2 is divided into individual semiconductor devices 12.

In the separation step, because wafer 2 is divided into semiconductor devices 12 by etching from the rear surface 2b of wafer 2, small cracks, chipping, and stress generated on the rear surface 2b of wafer 2 can be eliminated.

In detail, in the polishing step, as shown above, since mechanical polishing is performed, although the polishing speed can be raised, the aforesaid small cracks and so on might occur on the rear surface 2b of wafer 2. If wafer 2 is divided into the semiconductor devices 12 while ignoring them, some semiconductor devices 12 might be damaged, and not be able to operate as designed.

So, in the present embodiment, as shown above, in the polishing step, wafer 2 is not polished down to the thickness of the semiconductor device 12, but just down to a preset value, leading to a large remaining thickness of wafer 2, and in the separation step, wafer 2 is etched to the preset thickness of the semiconductor devices 12. Due to this, layers including small cracks and so on are removed. Different from mechanical processing, cracks and so on do not occur in etching. So, cracks are not left in the separated semiconductor devices 12, and semiconductor devices 12 of high reliability can be formed.

Note that in the etching processing, use may also be made of the plasma processing apparatus 20 as shown in FIG. 1 or chemical etching (wet etching). Further, when using the plasma processing apparatus 20, the volume ratio of the processing gas (SF₆ gas, Ar gas, O₂ gas) is the same as that in the etching step as shown in FIG. 2C, that is, the volume ratio of O₂ gas to SF₆ gas is set in a range from 11% to 25%.

In the present embodiment, in the etching processing shown in FIG. 2C using the plasma processing apparatus 20, or the etching processing shown in FIG. 2E using the plasma processing apparatus 20, in the same way, the volume ratio of O₂ gas to SF₆ gas is set in a range from 11% to 25%.

In contrast, in the related art, only SF₆ gas and Ar gas are used in the process gas, in which case S (sulfur) adheres to wafer 2 and the wall of the chamber 22, and the adhered to areas become white and impure.

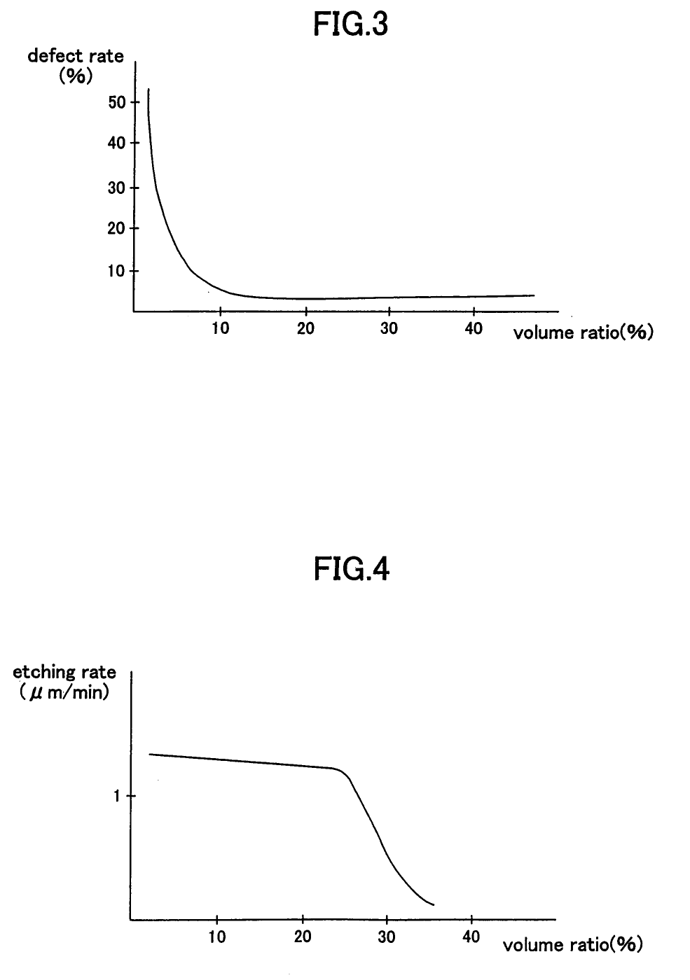

In the present invention, O₂ gas is added to the process gas in addition to SF₆ and Ar gases. Experiments were made while changing the volume ratio of O₂ gas to SF₆ gas. FIG. 3 shows the experimental results. In FIG. 3, the ordinate axis represents a rate of occurrence of a defective wafer (hereinafter, referred to as defect rate), and the abscissa axis represents the volume ratio of the O₂ gas to the SF₆ gas. In this experiment, for each volume ratio, the etching processing shown in FIG. 2C was performed for twenty semiconductor devices 12 using the plasma processing apparatus 20.

As shown in FIG. 3, the defect rate is high when the volume ratio of the O₂ gas to the SF₆ gas is zero, and the defect rate decreases when the volume ratio of the O₂ gas to the SF₆ gas increases, but when the volume ratio of the O₂ gas to the SF₆ gas is in the range from 0% to 11%, the defect rate is out of allowed range. Whereas, when the volume ratio of the O₂ gas to the SF₆ gas is above 11%, the defect rate is low, and is in the allowed range.

That is, when the volume ratio of the of the O₂ gas to the SF₆ gas is above 11%, in the course of etching, even if SF₆ molecules disintegrate, and fluoride (F) and sulfur are generated, these products are combined with of the O₂ gas and are exhausted. Due to this, contamination attachment to the wafer 2 or the chamber 22 does not happen, so the etching rate of the wafer 2 can be maintained, and at the same time, cleaning of the chamber 22 can be easily performed.

FIG. 4 shows a variation of the etching rate when the volume ratio of O₂ gas to the SF₆ gas was changed. In FIG. 4, the ordinate axis represents the etching rate, and the abscissa axis represents the volume ratio of O₂ gas to SF₆ gas.

As shown in FIG. 4, the etching rate drops abruptly when the volume ratio of O₂ gas to SF₆ gas exceeds 25%, so efficient etching cannot be performed, and manufacturing efficiently degrades drastically.

Accordingly, from the results in FIG. 3 and FIG. 4, by setting the volume ratio of O₂ gas to SF₆ gas in the range from 11% to 25%, it is found that the defect rate can be limited to the allowed range, while high manufacturing efficiency can be maintained.

While the invention has been described with reference to specific embodiments chosen for purpose of illustration, it should be apparent that the invention is not limited to these embodiments, but numerous modifications could be made thereto by those skilled in the art without departing from the basic concept and scope of the invention.

For example, in the above embodiment, the plasma processing apparatus 20 and dicing process for the wafer 2 performed using the plasma processing apparatus 20 were explained as an example of the plasma processing method and the plasma processing apparatus of the present invention, but the present invention is not limited to these, as it is widely applicable to plasma processing other than dicing, or partial plasma etching.

Summarizing the effect of the invention, according to the present invention as shown above, attachment of contaminates to a wafer or a chamber does not occur, and etching rate of a wafer can be maintained, while at the same time, cleaning of the chamber can also be easily performed.

The foregoing disclosure has been set forth merely to illustrate the invention and is not intended to be limiting. Since modifications of the disclosed embodiments incorporating the spirit and substance of the invention may occur to persons skilled in the art, the invention should be construed to include everything within the scope of the appended claims and equivalents thereof.

What is claimed is:

1. A method of dividing a wafer into a plurality of individual semiconductor devices, comprising the steps of:
forming grooves cut into a front surface of said wafer, said grooves demarcating circuits of said semiconductor devices formed on said front surface of said wafer;
polishing a back surface of said wafer while the front surface of said wafer is fixed to a support member; and
plasma etching the back surface of said wafer by a process gas and thereby dividing said wafer into the semiconductor devices, said process gas including a mixture of SF₆ gas (sulfur hexafluoride) gas, Ar (Argon) gas, and O₂ (oxygen) gas, wherein the volume ratio of the O₂ gas to the SF₆ gas is in a range from 11% to 25%.

2. A method of dividing a wafer into a plurality of individual semiconductor devices, comprising the steps of:
forming masks on the front surface of said wafer for masking each said semiconductor device formed on the front surface of the wafer;
plasma etching the front surface of said wafer between the masks to a predetermined depth using a process gas including a mixture of SF₆ (sulfur hexafluoride) gas, Ar (Argon) gas, and O₂ (oxygen) gas, wherein the volume ratio of the O₂ gas to the SF₆ gas is in a range from 11% to 25%;
polishing a back surface of said wafer while the front surface of said wafer is fixed to a support member; and
etching the back surface of said wafer and thereby dividing said wafer into the semiconductor devices.
